(19) United States
(12) Patent Application Publication
(10) Pub. No.: US 2020/0194707 A1
(43) Pub. Date: Jun. 18, 2020

(54) ORGANIC ELECTROLUMINESCENCE DEVICE AND DISPLAY DEVICE INCLUDING THE SAME

(71) Applicant: Samsung Display Co., Ltd., Yongin-si (KR)

(72) Inventors: Yeongrong Park, Osan-si (KR); Wonjong Kim, Suwon-si (KR); Dongkyu Seo, Suwon-si (KR); Junghee An, Hwaseong-si (KR); Byeongwook Yoo, Hwaseong-si (KR); Hyeongpil Kim, Hwaseong-si (KR); Byungseok Lee, Suwon-si (KR)

(21) Appl. No.: 16/597,853

(22) Filed: Oct. 10, 2019

(30) Foreign Application Priority Data
Dec. 12, 2018 (KR) 10-2018-0160303

(51) Int. Cl. H01L 51/50; H01L 27/32

(52) U.S. Cl. CPC H01L 51/5088; H01L 27/3244; H01L 2251/558; H01L 51/5012; H01L 51/5072; H01L 51/5056

(57) ABSTRACT

An organic electroluminescence device includes: a first electrode; a hole transport region disposed on the first electrode; an emission layer disposed on the hole transport region; an electron transport region disposed on the emission layer; and a second electrode disposed on the electron transport region. The hole transport region may include a first hole injection layer including a metal halogen compound, the metal halogen compound includes a halogen atom bonded to at least one of an alkali-metal, an alkali-earth metal, and a lanthanide metal, and wherein the hole transport region is substantially free of an organic compound.

### CROSS-REFERENCE TO RELATED APPLICATION

This patent application claims priority from and the benefit of Korean Patent Application No. 10-2018-0160303, filed on Dec. 12, 2018, which is hereby incorporated by reference for all purposes as if fully set forth herein.

### BACKGROUND

### Field

Exemplary embodiments of the invention relates to an organic electroluminescence device and a display device including the same.

### Discussion of the Background

The development of an organic electroluminescence display device as an image display device is being actively conducted. Unlike a liquid crystal display device, the organic electroluminescence display device is a so-called self-luminescent display device in which holes and electrons injected from a first electrode and a second electrode are recombined in an emission layer, and a light emission material, which is an organic compound contained in the emission layer, emits light to realize a display.

As the organic electroluminescence device, for example, an organic device has been known which includes: a first electrode; a hole transport layer disposed on the first electrode; an emission layer disposed on the hole transport layer; an electron transport layer disposed on the emission layer; and a second electrode disposed on the electron transport layer. Holes are injected from the first electrode, and the injected holes move through the hole transport layer and are injected into the emission layer. On the other hand, electrons are injected from the second electrode, and the injected electrons move through the electron transport layer and are injected into the emission layer. The holes and the electrons injected into the emission layer are recombined, thereby generating excitons in the emission layer. The organic electroluminescence device emits light by using the light generated when the excitons fall back to a ground state.

In the application of an organic electroluminescence device to a display device, an organic electroluminescence device having a low driving voltage, high luminous efficiency, and a long life has been required, and accordingly development on materials for an organic electroluminescence device capable of stably realizing the requirements has been continuously required.

The above information disclosed in this Background section is only for understanding of the background of the inventive concepts, and, therefore, it may contain information that does not constitute prior art.

### SUMMARY

Devices constructed according to exemplary embodiments of the invention are capable of provide an organic electroluminescence device including a metal halogen compound having high efficiency and a display device including the same.

Additional features of the inventive concepts will be set forth in the description which follows, and in part will be apparent from the description, or may be learned by practice of the inventive concepts.

According to one or more exemplary embodiments of the invention, an organic electroluminescence device includes: a first electrode; a hole transport region disposed on the first electrode; an emission layer disposed on the hole transport region; an electron transport region disposed on the emission layer; and a second electrode disposed on the electron transport region. The hole transport region may include a first hole injection layer including a metal halogen compound, the metal halogen compound includes a halogen atom bonded to at least one of an alkali-metal, an alkali-earth metal, and a lanthanide metal, and wherein the hole transport region is substantially free of an organic compound.

The metal halogen compound may have a dipole moment of 1.6 D (debye) or more and 150 D or less.

The metal halogen compound may have a work function value of 4.0 eV or less.

The metal halogen compound may have an interatomic bonding energy of 180 KJ/mol or more and 1200 KJ/mol or less.

The alkali-metal may include at least one of Li, Na, K, Rb, and Cs, the alkali-earth metal may include at least one of Be, Mg, Ca, Sr, and Ba, the lanthanide metal may include is at least one of La, Ce, Pr, Nd, Pm, Sm, Eu, Gd, Tb, Dy, Ho, Er, Tm, Yb, and Lu, and the halogen atom may include at least one of F, Cl, Br, and I.

The metal halogen compound may include KI.

The first hole injection layer may be disposed directly on the first electrode. A thickness of the first hole injection layer may be 1 Å or more and 30 Å or less.

The hole transport region may further include a second hole injection layer disposed on the first hole injection layer, and the second hole injection layer may contain an organic compound.

The second hole injection layer may further contain the metal halogen compound.

A volume ratio of the metal halogen compound with respect to the entire second hole injection layer may be 1% or more and 50% or less.

In the second hole injection layer, the organic compound and the metal halogen compound may be uniformly distributed.

A thickness of the second hole injection layer may be 1 Å or more and 100 Å or less.

According to one or more exemplary embodiments of the invention, an organic electroluminescence device includes: a first electrode; a hole transport region disposed on the first electrode; an emission layer disposed on the hole transport region; an electron transport region disposed on the emission layer; and a second electrode disposed on the electron transport region. The hole transport region may include a hole injection layer containing a metal halogen compound represented by the following formula: XₘYₙZ_{q}, wherein in the formula, X and Y may each independently be an alkali-metal, an alkali-earth metal, or a lanthanide metal, Z may be a halogen atom, m and n may each independently be an integer of 0 to 5, at least one of m or n may be an integer of 1 or larger, and q may be an integer of 1 to 5.

The metal halogen compound may have a dipole moment of 1.6 D (debye) or more and 150 D or less.

The alkali-metal may include at least one of Li, Na, K, Rb, and Cs, the alkali-earth metal may include at least one of Be, Mg, Ca, Sr, and Ba, the lanthanide metal may include at least one of La, Ce, Pr, Nd, Pm, Sm, Eu, Gd, Tb, Dy, Ho, Er, Tm, Yb, and Lu, and the halogen atom may include at least one of F, Cl, Br, and I.

According to one or more exemplary embodiments of the invention, a display device may include a plurality of organic electroluminescence devices. Each of the organic electroluminescence devices may include: a first electrode; a hole transport region disposed on the first electrode; an emission layer disposed on the hole transport region; an electron transport region disposed on the emission layer; and a second electrode disposed on the electron transport region. The hole transport region may include a first hole injection layer including a metal halogen compound including a halogen atom bonding with a low-work function metal having low functions with values of 4.0 eV or less, and wherein the hole transport region is substantially free of contain an organic compound.

The metal halogen compound may have a dipole moment of 1.6 D (debye) or more and 150 D or less.

The low-work function metal may include at least a one Li, Na, K, Rb, Cs, Be, Mg, Ca, Sr, Ba, La, Ce, Pr, Nd, Pm, Sm, Eu, Gd, Tb, Dy, Ho, Er, Tm, Yb, and Lu, and the halogen atom may include at least one of F, Cl, Br, and I.

The hole transport region may further include a second hole injection layer disposed on the first hole injection layer, and wherein the hole transport region comprising an organic compound and the metal halogen compound.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the inventive concepts.

FIG. 1 is a perspective view of a display device according to an exemplary embodiment.

FIG. 2 is a cross-sectional view taken along a sectional line I-I′ in FIG. 1.

FIGS. 3, 4, and 5 are cross-sectional views schematically illustrating an organic electroluminescence device according to an exemplary embodiment.

FIG. 6 is a graph showing current efficiency according to luminance of an organic electroluminescence device according to an exemplary embodiment.

### DETAILED DESCRIPTION

In the following description, for the purposes of explanation, numerous specific details are set forth in order to provide a thorough understanding of various exemplary embodiments or implementations of the invention. As used herein “embodiments” and “implementations” are interchangeable words that are non-limiting examples of devices or methods employing one or more of the inventive concepts disclosed herein. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

In the accompanying drawings, the size and relative sizes of elements may be exaggerated for clarity and/or descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, exemplary embodiments of the inventive concepts will be described in detail with reference to the accompanying drawings.

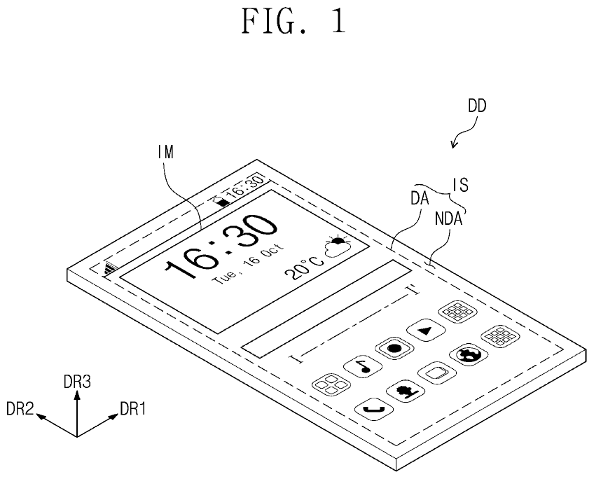

FIG. 1 is a perspective view of a display device DD according to an exemplary embodiment. As illustrated in FIG. 1, the display device DD may display an image IM through a display surface IS. The display surface IS is parallel to a plane defined by a first direction axis DR1 and a second direction axis DR2. A third direction axis DR3 indicates a normal direction of the display surface IS, i.e., a thickness direction of the display device DD.

A front surface (or a top surface) and a back surface (or a bottom surface) of each member or unit described below are defined according to the third direction axis DR3. However, the first to third direction axes DR1, DR2 and DR3 illustrated in the exemplary embodiment are merely exemplary directions, and the directions indicated by the first to third direction axes DR1, DR2 and DR3 are relative concepts, so that the directions may change into other directions. Hereinafter, the first to third directions refer to the same reference numerals as the directions indicated by the first to third direction axes DR1, DR2, and DR3, respectively.

In an exemplary embodiment, the display device DD having a planar display surface is illustrated, but the exemplary embodiments are not limited thereto. The display device DD may include a curved display surface or a stereoscopic display surface. The stereoscopic display surface may include a plurality of display areas indicating different directions from each other, and may also include, for example, a polygonal columnar display surface.

The display device DD according to an exemplary embodiment may be a rigid display device. However, the exemplary embodiments are not limited thereto, and the display device DD according to the exemplary embodiments may also be a flexible display device DD. In an exemplary embodiment, the display device DD applicable to a portable terminal is exemplarily illustrated. Although not illustrated herein, electronic modules, a camera module, a power module, etc. mounted on a main board are accommodated in a housing HS to constitute the portable terminal. The display device DD according to the exemplary embodiment may be applied to not only a large-sized electronic device such as a television, a monitor but also a small- or medium-sized electronic device such as a tablet, a car navigation system, a game machine, a smart watch.

As illustrated FIG. 1, the display surface IS may include a display area DA in which the image IM is displayed and a non-display area NDA adjacent to the display area DA. The non-display area NDA is an area in which the image is not displayed. As an example of the image IM, icon images are illustrated in FIG. 1.

As illustrated in FIG. 1, the display area DA may have a rectangular shape. The non-display area NDA may surround the display area DA. However, the exemplary embodiments are not limited thereto, and the shape of the display area DA and the shape of the non-display area NDA may be relatively designed.

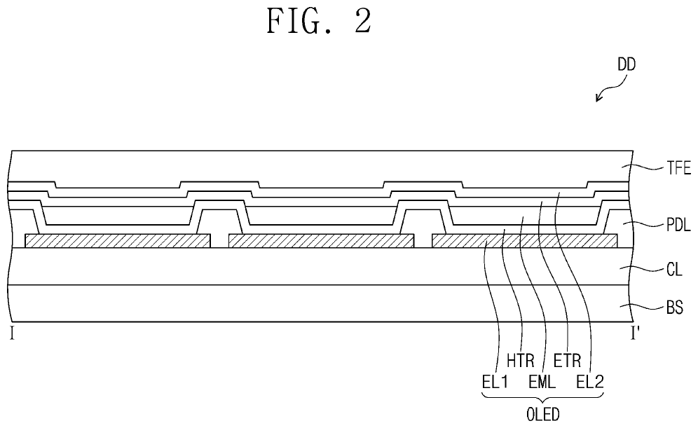

FIG. 2 is a cross-sectional view taken along a sectional line I-I′ in FIG. 1. FIG. 2 is is a simple view illustrating the lamination relationship between the components constituting the display device DD.

The display device DD may include a base substrate BS, a circuit layer CL, a plurality of organic electroluminescence devices OLED, a plurality of pixel defining layers PDL, and a thin film encapsulation layer TFE. The circuit layer CL may be disposed on the base substrate BS, the plurality of organic electroluminescence devices OLED and the plurality of pixel defining layers PDL may be disposed on the circuit layer CL, and the thin film encapsulation layer TFE may be disposed on the organic electroluminescence devices OLED. Although not illustrated herein, the display device DD may further include other elements, and for example, a glass substrate (not illustrated) or a cover substrate (not illustrated) may be further disposed on the thin film encapsulation layer TFE.

The base substrate BS may have a laminated structure including a silicon substrate, a plastic substrate, a glass substrate, an insulation film, or a plurality of insulation layers.

The circuit layer CL may include a plurality of transistors (not illustrated). Each of the electroluminescence devices OLED may be electrically connected to each of a plurality of transistors (not illustrated), and may receive signals.

Each of the organic electroluminescence devices OLED may be disposed between the plurality of pixel defining layers PDL, and the organic electroluminescence devices OLED may be disposed apart from each other on a plane. In the specification, “on a plane” may mean when the display device DD is viewed in the third direction DR3 (the thickness direction).

Each of the organic electroluminescence devices OLED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR.

Although it is illustrated herein that the hole transport region HTR and the electron transport region ETR are disposed in the same layer, but the exemplary embodiments are not limited thereto, and at least one of the hole transport region HTR or the electron transport region ETR may be separately disposed in each of the organic electroluminescence devices OLED.

Although it is illustrated herein that the emission layer EML is separately disposed in each of the organic electroluminescence devices OLED, but the exemplary embodiments are not limited thereto, and the emission layer EML may be disposed in the same layer of the organic electroluminescence devices OLED.

The pixel defining layer PDL may be disposed between the organic electroluminescence devices OELD, and may expose at least a portion of each of the first electrodes EL1. The pixel defining layer PDL may be formed of a polymer resin or an inorganic material. Alternatively, the pixel defining layer PDL may be formed by further including an inorganic material in addition to the polymer resin. On the other hand, the pixel defining layer PDL may be formed by including a light absorbing material, or may be formed by including a black pigment or a black dye.

The thin film encapsulation layer TFE may directly cover the second electrode EL2. The thin film encapsulation layer TFE may include an organic layer containing an organic material and an inorganic layer containing an inorganic material. In an exemplary embodiment, a capping layer (not illustrated) which covers the second electrode EL2 may be further disposed. At this time, the thin film encapsulation layer TFE may directly cover the capping layer.

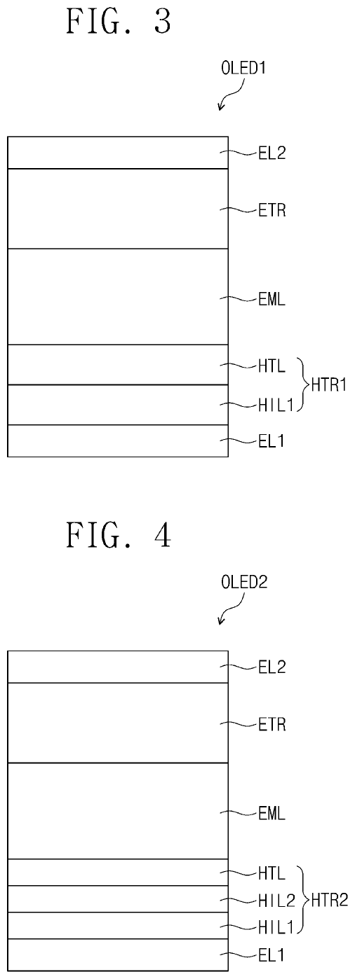

FIGS. 3, 4, and 5 are cross-sectional views schematically illustrating organic electroluminescence devices OLED1, OLED2, and OLED3 according to an exemplary embodiment. The organic electroluminescence devices illustrated in FIGS. 3, 4, and 5 may correspond to any one of the organic electroluminescence devices OLED illustrated in FIG. 2.

Referring to FIGS. 3, 4, and 5, each of the organic electroluminescence devices OLED1, OLED2, and OLED3 may include a first electrode EL1, a hole transport regions HTR1, HTR2, and HTR3, an emission layer EML, an electron transport region ETR, and a second electrode EL2 which are sequentially laminated, but the exemplary embodiments are not limited thereto. In the hole transport regions HTR1, HTR2 and HTR3, for example, the hole transport layer HTL may be omitted.

The first electrode EL1 has conductivity. The first electrode EL1 may be formed of a metal alloy or a conductive compound. The first electrode EL1 may be an anode. In addition, the first electrode EL1 may be a pixel electrode. The first electrode EL1 may be a transmissive electrode, a transflective electrode or a reflective electrode. When the first electrode EL1 is a transmissive electrode, the first electrode EL1 may include transparent metal oxide such as indium tin oxide (ITO), indium zinc oxide (IZO), zinc oxide (ZnO), or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, or a compound or mixture thereof (for example, a mixture of Ag and Mg). Alternatively, the first electrode EL1 may have a multi-layered structure including a reflective film or a transflective film formed of the above material, and a transparent conductive film formed of ITO, IZO, ZnO, ITZO, or the like. The first electrode EL1, for example, may have a three-layer structure of ITO/Ag/ITO, but the exemplary embodiments are not limited thereto. A thickness of the first electrode EL1 may be about 1000-10000 Å, for example, about 1000-3000 Å.

The hole transport regions HTR1, HTR2 and HTR3 may include a first hole injection layer HIL1. The first hole injection layer HIL1 may contain a metal halogen compound, in which a halogen atom is bonded to at least one of an alkali-metal, an alkali-earth metal, or a lanthanide metal, and may substantially not include an organic compound.

In the description, the term “substantially not include” or the term “substantially free of” may mean that the material does not exceed the range of ratios that can inevitably be included in the process of the art. For example, even if another organic layer (for example, a second hole injection layer which will be described later) is deposited on the first hole injection layer HIL1, a trace of an organic compound composed of another organic layer in the first hole injection layer HIL1 is inevitably added in the process, it is understood herein as not substantially including an organic compound.

The first hole injection layer HIL1 may contain a metal halogen compound that formed by bonding of a halogen atom and a low-work function metal having low functions with values of 4.0 eV or less, and may not contain an organic compound. The low-work function metal may be an alkali-metal, an alkali-earth metal, or a lanthanide metal as described.

The alkali-metal may be lithium (Li), sodium (Na), potassium (K), rubidium (Rb), or cesium (Cs), the alkali-earth metal may be beryllium (Be), magnesium (Mg), calcium (Ca), strontium (Sr), or barium (Ba), the lanthanide metal may be lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), or lutetium (Lu), and the halogen atom may be fluorine (F), chlorine (Cl), bromine (Br), or iodine (I). More specifically, the lanthanide metal may be samarium (Sm) or ytterbium (Yb).

The metal halogen compound of an exemplary embodiment may be represented by Formula 1:

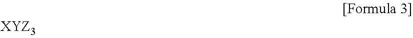

In Formula 1, X and Y may each independently be an alkali-metal, an alkali-earth metal, or a lanthanide metal, and Z may be a halogen atom.

The numbers “m” and “n” may each independently be an integer of 0 to 5, and at least one of m or n may be an integer of 1 or larger. The numbers “m” and “n” may be the same as or different from each other. For example, m may be 1, and n may be 0. The number “q” may be an integer of 1 to 5, but the exemplary embodiments are not limited thereto. In Formula 1, the numbers “n,” “m,” and “q” may be appropriately selected depending on the kinds of the elements X, Y, and Z, respectively.

In embodiment, Formula 1 may be represented by Formula 2-1, Formula 2-2, and Formula 2-3:

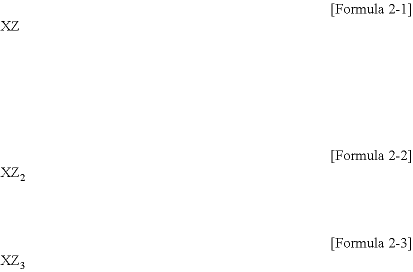

In Formula 2-1, X may be an alkali-metal, in Formula 2-2, X may be an alkali-earth metal, and in Formula 2-3, X may be a lanthanide metal. In Formulae 2-1, 2-2, and 2-3, Z may be the same as defined in Formula 1.

Specifically, Formulae 2-1, 2-2, and 2-3 may be LiZ, NaZ, KZ, RbZ, CsZ, BeZ₂, MgZ₂, CaZ₂, SrZ₂, BaZ₂, YbZ₃, or SmZ₃. In Formulae 2-1, 2-2, and 2-3, Z may be a halogen atom. More specifically, Formulae 2-1, 2-2, and 2-3 may be LiF, NaF, KI, RbI, CaF₂, or YbF₃.

In an exemplary embodiment, Formula 1 may be represented by Formula 3:

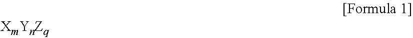

In Formula 3, X may be an alkali-metal, and Y may be an alkali-metal or a lanthanide metal. Z may be the same as defined in Formula 1. Specifically, Formula 3 may be KYbZ₃, RbYbZ₃, CsYbZ₃, NaYbZ₃, LiYbZ₃, RbSmZ₃, CsSmZ₃, KSmZ₃, NaSmZ₃, LiSmZ₃, RbMgZ₃, CsMgZ₃, KMgZ₃, NaMgZ₃, or LiMgZ₃. In Formulae above, Z may be a halogen atom. More specifically, the Formula 3 may be RbYbI₃.

However, Formulae 2-1, 2-2, and 2-3 and Formula 3 described above are exemplary descriptions of Formula 1, and the exemplary embodiments are not limited thereto.

A dipole moment of the metal halogen compound according to an exemplary embodiment may be 1.6 D (debye) or more.

Typically, a high-work function metal is used as a hole injection material in the hole injection layer to improve the hole injection efficiency by reducing the energy gap between the anode and the hole injection layer. On the other hand, although the metal halogen compound according to an exemplary embodiment contains a low-work function metal, the metal halogen compound may improve the hole injection efficiency used as a hole injection material since the compound has the dipole moment of 1.6 D or more.

When the dipole moment of the metal halogen compound is 1.6 D or more, a Fermi level of the first electrode EL1 may be lowered. The work function may be represented by a difference value between the outgoing level and the Fermi level, and the work function value of the first electrode EL1 may be increased when the Fermi level of the material composed of the first electrode is lowered. Accordingly, the energy gap between the first hole injection layer HIL1 and the first electrode EL1 is reduced, so that the hole injection barrier is lowered and the hole injection efficiency may be improved.

When the dipole moment of the metal halogen compound is 1.6 D or less, the Fermi level of the first electrode EL1 may not sufficiently lowered, and the hole injection barrier between the first hole injection layer HIL1 and the first electrode EL1 may not sufficiently lowered, whereby the hole injection efficiency may not be improved or may be deteriorated.

An upper limit value of the dipole moment in the metal halogen compound of an exemplary embodiment is not particularly limited, and it is acceptable of any value of the dipole moment that the metal halogen compound may have. For example, a ferroelectric material such as RbYbI₃ may have a dipole moment of 100 D or more. For example, the upper limit value of the dipole moment in the metal halogen compound of an exemplary embodiment may be 150 D.

The interatomic bonding energy of the metal halogen compound may be 180 KJ/mol or more. When the interatomic bonding energy of the metal halogen compound is 180 KJ/mol or less, the metal atoms may dissociate from the metal halogen compound, and the hole injection barrier may be increased, whereby the hole injection efficiency may be deteriorated.

An upper limit value of the interatomic bonding energy in the metal halogen compound of an exemplary embodiment is not particularly limited, and it is acceptable of any value of the interatomic bonding energy that the metal halogen compound may have. For example, the upper limit value of the interatomic bonding energy in the metal halogen compound of an exemplary embodiment may be 1200 KJ/mol.

The first hole injection layer HIL1 may be disposed directly on the first electrode EL1. A thickness of the first hole injection layer HIL1 may be 1-30 Å. The thickness of the first hole injection layer HIL1 for example, may be 5 Å.

When the thickness of the first hole injection layer HIL1 is 1 Å or less, it may be difficult to uniformly deposit the first hole injection layer HIL1 thereby being ununiformed distribution. In addition, when the first hole injection layer HIL1 is deposited too thin, the original hole injection function may not be sufficiently exhibited, thereby deteriorating the device efficiency. When the thickness of the first hole injection layer HIL1 is 30 Å or more, a high driving voltage may be required, thereby deteriorating the device efficiency.

Referring to FIG. 4, a second hole injection layer HIL2 may be directly disposed on the first hole injection layer HIL1. The second hole injection layer HIL2 may contain an organic compound. The second hole injection layer HIL2 may contain, for example, at least one of a phthalocyanine compound (such as copper phthalocyanine), N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′4″-tris(N,N-diphenylamino) triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/Camphorsulfonic acid (PANI/CSA), polyaniline/poly(4-styrenesulfonate) (PANI/PSS), N,N′-di(1-naphthyl)-N,N′-diphenylbenzidine (NPB), triphenylamine-containing polyetherketone (TPAPEK), 4-isopropyl-4′-methyldiphenyliodoniumtetrakis(pentafluorophenyl)borate, and dipyrazino[2,3-f:2′,3′-h]quinoxaline-2,3,6,7,10,11-hexacarbonitrile (HAT-CN). However, the exemplary embodiments are not limited thereto, the second hole injection layer HIL2 may contain one or more of known hole injection materials.

The second hole injection layer HIL2 may both the organic compound and the metal halogen compound described above. At this time, the organic compound and the metal halogen compound may be co-deposited and disposed. The described explanation for the metal halogen compound may be equally applied to the metal halogen compound contained in the second hole injection layer HIL2.

When both the organic compound and the metal halogen compound are contained in the second hole injection layer HIL2, the low-work function metal atoms bring electrons from the organic compound, whereby the second hole injection layer HIL2 may exhibit a p-doped effect. Accordingly, the hole injection efficiency may be improved. Particularly, as the first hole injection layer HIL1 and the second hole injection layer HIL2 which respectively have the improvement effect of the hole injection efficiency are disposed together in the hole transport regions HTR2 and HTR3, the improvement effect of the hole injection efficiency may be further increased.

The metal halogen compound may have a volume ratio of 1-50% with respect to the entire second hole injection layer HIL2. When the ratio of the metal halogen compound is 1% or less, the above described p-doped effect may be reduced, thereby deteriorating the device efficiency. When the ratio of the metal halogen compound is 50% or more, the functions of the second hole injection layer HIL2 and the first hole injection layer HIL1 may not be clearly distinguished, and as the thicknesses of the hole transport regions HTR2 and HTR3 are thicker, the driving voltage required for driving may be higher.

The organic compound and the metal halogen compound may be uniformly distributed in the second hole injection layer HIL2. Accordingly, the p-doping characteristics may be exhibited throughout the entire second hole injection layer HIL2.

A thickness of the second hole injection layer HIL2 may be 1-100 Å. When the thickness of the second hole injection layer HIL2 is 1 Å or less, it may be difficult to uniformly deposit the second hole injection layer HIL2, thereby being ununiformed distribution. In addition, when the second hole injection layer HIL2 is deposited too thin, the original hole injection function may not be sufficiently exhibited, thereby deteriorating the device efficiency. When the thickness of the second hole injection layer HIL2 is 30 Å or more, a high driving voltage may be required, thereby deteriorating the device efficiency.

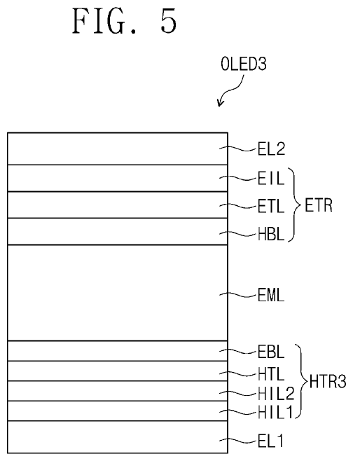

Referring to FIG. 5, the hole transport region HTR3 may further include at least one of a hole transport layer HTL, a hole buffer layer (not illustrated), or an electron blocking layer in addition to the first hole injection layer HIL1 and the second hole injection layer HIL2.

The hole transport layer HTL may contain, for example, at least one of a carbazole-based derivative (such as N-phenylcarbazole or polyvinylcarbazole), a fluorine-based derivative, a triphenylamine-based derivative (such as N,N′-bis(3-methylphenyl)-N,N′-diphenyl-(1,1-biphenyl)-4,4′-diamine (TPD) or 4,4′,4″-tris(N-carbazolyl)triphenylamine (TCTA)), N,N′-di(1-naphthyl)-N,N′-diphenylbenzidine (NPB), 4,4′-cyclohexylidenebis[N,N-bis(4-methylphenyl)benzenamine] (TAPC), 4,4′-bis[N,N′-(3-tolyl)amino]-3,3′-dimethylbiphenyl (HMTPD), 1,3-bis(N-carbazolyl)benzene (mCP), and the like. However, the exemplary embodiments are not limited thereto, the hole transport layer HTL may contain one or more of known hole transport materials.

The hole buffer layer (not illustrated) may improve the light emission efficiency by compensating a resonance distance according to the wavelength of the light emitted from the emission layer EML. The materials contained in the hole transport region HTR3 may also be used as materials contained in the hole buffer layer (not illustrated). The electron blocking layer EBL may be a layer which prevents or suppresses electron injection from the electron transport region ETR to the hole transport region HTR3.

Thicknesses of the hole transport regions HTR1, HTR2, and HTR3 may be about 1-10000 Å, for example, about 1-5000 Å. Although each of the layers included in the hole transport regions HTR1, HTR2, and HTR3 is illustrated to have the equal thickness in FIGS. 3, 4, and 5, each of the layers included in the hole transport regions HTR1, HTR2, and HTR3 may have the different thickness.

A thickness of the hole transport layer HTL may be about 30-1000 Å. A thickness of the electron blocking layer EBL, for example, may be about 10-1000 Å. When the thicknesses of the hole transport regions HTR1, HTR2, and HTR3 satisfy the described ranges, the satisfying hole transport performance may be achieved without substantial rise of a driving voltage.

The emission layer EML may be disposed on the hole transport regions HTR1, HTR2, and HTR3. The emission layer EML may have a thickness of, for example, about 100-1000 Å or about 100-300 Å. The emission layer EML may have a structure of: a single layer formed of a single material; a single layer formed of a plurality of different materials; or a multi-layer having a plurality of layers formed of a plurality of different materials.

The hole transport regions HTR1, HTR2, and HTR3 may be formed using various methods such as a vacuum deposition method, a spin coating method, a casting method, a Langmuir-Blodgett (LB) method, an inkjet printing method, a laser printing method, or a laser induced thermal imaging (LITI) method.

The emission layer EML in the organic electroluminescence devices OLED1, OLED2, and OLED3 of an exemplary embodiment may include an anthracene derivative, a pyrene derivative, a fluoranthene derivative, a chrysene derivative, a dihydrobenzanthracene derivative, or a triphenylene derivative. Specifically, the emission layer EML may include an anthracene derivative or a pyrene derivative.

The emission layer EML may include a typical material known in the art as a host material. For example, the emission layer EML may include a host material, for example, at least one of bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TcTa), and 1,3,5-tris(N-phenylbenzimidazole-2-yl)benzene (TPBi). However, the exemplary embodiments are not limited thereto, and for example, tris(8-hydroxyquinolino)aluminum (Alq₃), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), bis[2-(diphenylphosphino)phenyl] ether oxide (DPEPO), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), 2,8-bis(diphenylphosphoryl)dibenzofuran (PPF), and the like may be used as a host material.

In an exemplary embodiment, the emission layer EML may include a known dopant material, for example, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), or N-(4-((E)-2-(6-((E)-4-(diphenylamino)styryl)naphthalen-2-yl)vinyl)phenyl)-N-phenylbenzenamine (N-BDAVBi)), perylene and derivatives thereof (for example, 2,5,8,11-tetra-t-butylperylene (TBP)), pyrene and derivatives thereof (for example, 1,1-dipyrene, 1,4-dipyrenylbenzene, and 1,4-bis(N,N-diphenylamino)pyrene), or the like.

The emission layer EML may emit any one of red light, green light, or blue light.

In the organic electroluminescence devices OLED1, OLED2, and OLED3 of an exemplary embodiment, the electron transport region ETR may be disposed on the emission layer EML. The electron transport region ETR may include at least one of a hole blocking layer HBL, an electron transport layer ETL, or an electron injection layer EIL, but the exemplary embodiments are not limited thereto.

The electron transport region ETR may have a structure of: a single layer formed of a single material; a single layer formed of a plurality of different materials; or a multi-layer having a plurality of layers formed of a plurality of different materials.

For example, the electron transport region ETR may have a structure of a single layer which is an electron injection layer EIL or an electron transport layer ETL, or may have a structure of a single layer formed of an electron injection material and an electron transport material. Alternatively, the electron transport region ETR may have a structure of a single layer formed of a plurality of different materials, or may have a structure of, sequentially laminated from the emission layer EML, electron transport layer ETL/electron injection layer EIL or hole blocking layer HBL/electron transport layer ETL/electron injection layer EIL, but the exemplary embodiments are not limited thereto. A thickness of the electron transport region ETR may be, for example, from about 1000-1500 Å.

The electron transport region ETR may be formed using various methods such as a vacuum deposition method, a spin coating method, a casting method, a Langmuir-Blodgett (LB) method, an inkjet printing method, a laser printing method, or a laser induced thermal imaging (LITI) method.

When the electron transport region ETR includes the electron transport layer ETL, the electron transport region ETR may include an anthracene-based compound. However the exemplary embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), and a mixture thereof. A thickness of the electron transport layer ETL may be about 100-1000 Å, for example, about 150-500 Å. When the thickness of the electron transport layer ETL satisfies the described range, the satisfying electron transport performance may be achieved without substantial rise of a driving voltage.

When the electron transport region ETR includes the electron injection layer EIL, the electron transport region ETR may employ: a lanthanide metal such as LiF, lithium quinolate (LiQ), Li₂O, BaO, NaCl, CsF, and Yb; or a halogenated metal such as RbCl and RbI, but the exemplary embodiments are not limited thereto. The electron injection layer EIL may also be formed of a mixture of an electron transport material and an insulating organo-metal salt. The organo-metal salt may be a material having an energy band gap of about 4 eV or more. Specifically, the organo-metal salt may contain, for example, a metal acetate, a metal benzoate, a metal acetoacetate, a metal acetylacetonate, or a metal stearate. Thicknesses of the electron injection layers EIL may be about 1-100 Å, for example, about 3-90 Å. When the thicknesses of the electron injection layers EIL satisfy the described range, the satisfying electron injection performance may be achieved without substantial rise of a driving voltage.

The electron transport region ETR may include a hole blocking layer HBL as described above. The hole blocking layer HBL may contain, for example, at least one of 2,9-dimethyl-4,7-diphenyl-1,10-phenanthroline (BCP) or 4,7-diphenyl-1,10-phenanthroline (Bphen), but the exemplary embodiments are not limited thereto.

The second electrode EL2 may be disposed on the electron transport region ETR. The second electrode EL2 may be a common electrode or a negative electrode. The second electrode EL2 may be a transmissive electrode, a transflective electrode, or a reflective electrode. When the second electrode EL2 is a transmissive electrode, the second electrode EL2 may be formed of transparent metal oxide, for example, indium tin oxide (ITO), indium zinc oxide (IZO), zinc oxide (ZnO), indium tin zinc oxide (ITZO), or the like.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, and a compound or a mixture thereof (for example, a mixture of Ag and Mg). Alternatively, the second electrode EL2 may be a structure which has a plurality of layers including: a reflective layer or a transflective layer formed of the described materials; and a transparent conductive layer formed of ITO, IZO, ZnO, ITZO, or the like.

Although not illustrated, the second electrode EL2 may be connected to an auxiliary electrode. When the second electrode EL2 is connected to the auxiliary electrode, the resistance of the second electrode EL2 may be reduced.

Meanwhile, although not illustrated in Figures, capping layers (not illustrated) may be further disposed on the second electrodes EL2 of the organic electroluminescence devices OLED1, OLED2, and OLED3 of an exemplary embodiment. The capping layers (not illustrated) may include, for example, α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)-triphenylamine (TCTA), N,N′-bis(naphthalene-1-yl), and the like.

In the organic electroluminescence devices OLED1, OLED2, and OLED3, as a voltage is applied to the first electrode EL1 and the second electrode EL2 respectively, the holes injected from the first electrode EL1 may move through the hole transport region HTR to the emission layer EML, and the electrons injected from the second electrode EL2 may move through the electron transport region ETR to the emission layer EML. The electrons and the holes may be recombined in the emission layer EML to generate excitons, and the excitons may emit light when the excitons fall back from an excited state to a ground state.

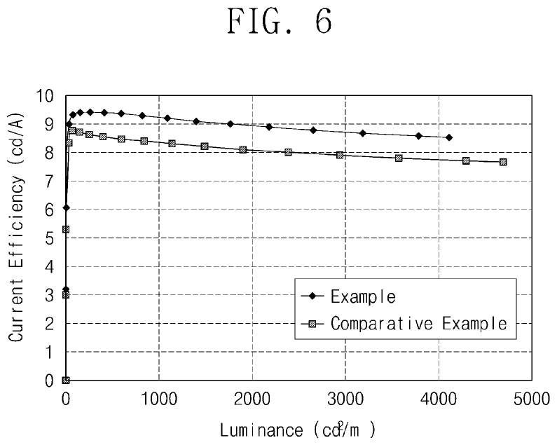

FIG. 6 is a graph showing current efficiency according to luminance of an organic electroluminescence device according to an exemplary embodiment.

Hereinafter, organic electroluminescence devices OLED1, OLED2, and OLED3 which respectively include a first hole injection layer HIL1 containing a metal halogen compound according to an exemplary embodiment will be explained in more detail with reference to example, comparative example, and FIG. 6. In addition, an exemplary embodiment illustrated hereinafter is only an example to assist the understanding of the inventive concepts, and the scope of the exemplary embodiments are not limited thereto.

(Manufacture of Organic Electroluminescent Device)

In the organic electroluminescence device according to example, using KI, a first hole injection layer was deposited to a thickness of 5 Å so as to be directly disposed on a first electrode, and a second hole injection layer only containing an organic compound was formed on the first hole injection layer. The organic electroluminescence device according to comparative example was manufactured in the same manner as the example except that the first hole injection layer was not disposed.

(Evaluation of Characteristics of Organic Electroluminescence Device)

To evaluate the characteristics of the organic electroluminescence device according to example and comparative example, a driving voltage and current efficiency of the device were measured. The evaluation results in Table 1 represent the current efficiency (cd/A) at the driving voltage of 4.6 V.

TABLE 1

| | Driving voltage | Current efficiency |
|---|---|---|
| | (V) | (cd/A) |
| Example | 4.6 | 9.2 |
| Comparative Example | 4.6 | 8.3 |

Referring to the results in Table 1, example shows the current efficiency of 9.2 cd/A at the driving voltage of 4.6 V, and comparative example shows the current efficiency of 8.3 cd/A at the driving voltage of 4.6 V. In the case of example, the improvement effect of the current efficiency of 10% or more is obtained compared with comparative example.

FIG. 6 is a graph showing the current efficiency by the luminance in example and comparative example respectively at the same driving voltage of 4.6 V. Referring to FIG. 6, example obtains the improvement effect of the current efficiency of about 10% or more compared with comparative example in the entire luminance region.

Accordingly, it may be considered that the first hole injection layer composed of the metal halogen compound is further added to improve the hole injection efficiency.

According to an exemplary embodiment, the organic electroluminescence device and the display device including the same may have a low driving voltage and improved efficiency.

Although certain exemplary embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. An organic electroluminescence device comprising:
a first electrode;
a hole transport region disposed on the first electrode;
an emission layer disposed on the hole transport region;
an electron transport region disposed on the emission layer; and
a second electrode disposed on the electron transport region,
wherein the hole transport region comprises a first hole injection layer comprising a metal halogen compound, the metal halogen compound comprises a halogen atom bonded to at least one of an alkali-metal, an alkali-earth metal, and a lanthanide metal, and
wherein the hole transport region is substantially free of an organic compound.

2. The organic electroluminescence device of claim 1, wherein the metal halogen compound has a dipole moment of 1.6 D (debye) or more and 150 D or less.

3. The organic electroluminescence device of claim 1, wherein the metal halogen compound has a work function value of 4.0 eV or less.

4. The organic electroluminescence device of claim 1, wherein the metal halogen compound has an interatomic bonding energy of 180 KJ/mol or more and 1200 KJ/mol or less.

5. The organic electroluminescence device of claim 1, wherein:
the alkali-metal comprises at least one of Li, Na, K, Rb, and Cs;
the alkali-earth metal comprises at least one of Be, Mg, Ca, Sr, and Ba;
the lanthanide metal comprises at least one of La, Ce, Pr, Nd, Pm, Sm, Eu, Gd, Tb, Dy, Ho, Er, Tm, Yb, and Lu; and
the halogen atom comprises at least one of F, Cl, Br, and I.

6. The organic electroluminescence device of claim 1, wherein the metal halogen compound comprises KI.

7. The organic electroluminescence device of claim 1, wherein the first hole injection layer is disposed directly on the first electrode.

8. The organic electroluminescence device of claim 1, wherein a thickness of the first hole injection layer is 1 Å or more and 30 Å or less.

9. The organic electroluminescence device of claim 1, wherein the hole transport region further comprises a second hole injection layer disposed on the first hole injection layer, and the second hole injection layer comprises an organic compound.

10. The organic electroluminescence device of claim 9, wherein the second hole injection layer further comprises the metal halogen compound.

11. The organic electroluminescence device of claim 10, wherein a volume ratio of the metal halogen compound with respect to the entire second hole injection layer is 1% or more and 50% or less.

12. The organic electroluminescence device of claim 10, wherein, in the second hole injection layer, the organic compound and the metal halogen compound are uniformly distributed.

13. The organic electroluminescence device of claim 10, wherein a thickness of the second hole injection layer is 1 Å or more and 100 Å or less.

14. An organic electroluminescence device comprising:
a first electrode;
a hole transport region disposed on the first electrode;
an emission layer disposed on the hole transport region;
an electron transport region disposed on the emission layer; and
a second electrode disposed on the electron transport region,
wherein the hole transport region comprises a hole injection layer containing a metal halogen compound represented by the following formula: XₘYₙZ_{q}, wherein in the formula, X and Y are each independently an alkali-metal, an alkali-earth metal, or a lanthanide metal, Z is a halogen atom, m and n are each independently an integer of 0 to 5, and at least one of m or n is an integer of 1 or larger, and q is an integer of 1 to 5.

15. The organic electroluminescence device of claim 14, wherein the metal halogen compound has a dipole moment of 1.6 D (debye) or more and 150 D or less.

16. The organic electroluminescence device of claim 14, wherein:
the alkali-metal comprises at least one of Li, Na, K, Rb, and Cs;
the alkali-earth metal comprises at least one of Be, Mg, Ca, Sr, and Ba;
the lanthanide metal comprises at least one of La, Ce, Pr, Nd, Pm, Sm, Eu, Gd, Tb, Dy, Ho, Er, Tm, Yb, and Lu; and
the halogen atom comprises at least one of F, Cl, Br, and I.

17. A display device comprising a plurality of organic electroluminescence devices,
wherein each of the organic electroluminescence devices comprises:
a first electrode;
a hole transport region disposed on the first electrode;
an emission layer disposed on the hole transport region;
an electron transport region disposed on the emission layer; and
a second electrode disposed on the electron transport region,
wherein the hole transport region comprises a first hole injection layer comprising a metal halogen compound comprising a halogen atom bonding with a low-work function metal having low functions with values of 4.0 eV or less, and
wherein the hole transport region is substantially free of an organic compound.

18. The display device of claim 17, wherein the metal halogen compound has a dipole moment of 1.6 D (debye) or more and 150 D or less.

19. The display device of claim 17, wherein the low-work function metal comprises at least one of Li, Na, K, Rb, Cs, Be, Mg, Ca, Sr, Ba, La, Ce, Pr, Nd, Pm, Sm, Eu, Gd, Tb, Dy, Ho, Er, Tm, Yb, and Lu, and the halogen atom comprises at least one of F, Cl, Br, and I.

20. The display device of claim 17, wherein the hole transport region further comprises a second hole injection layer disposed on the first hole injection layer, and
wherein the hole transport region comprising an organic compound and the metal halogen compound.
